(19) United States
(12) Patent Application Publication
(10) Pub. No.: US 2008/0238573 A1
(43) Pub. Date: Oct. 2, 2008

(54) Coupling Circuit and Network Device for Power Line Communication

(75) Inventor: Shohei YAMAZAKI, Hamamatsu-shi (JP)

Correspondence Address: CROWELL & MORING LLP;INTELLECTUAL PROPERTY GROUP, P.O. BOX 14300, WASHINGTON, DC, 20044-4300, US

(73) Assignee: YAMAHA CORPORATION, Hamamatsu-shi (JP)

(21) Appl. No.: 12/057,680

(22) Filed: Mar. 28, 2008

(30) Foreign Application Priority Data
Mar. 29, 2007 (JP) 2007-086601

(51) Int. Cl. H03H 7/00; H03H 7/01

(52) U.S. Cl. 333/177

(57) ABSTRACT

A coupling circuit is used in a power line communication system for bridging a signal of a high frequency between lines of a single-phase three-line type which feed an electric current having a low frequency as compared to the high frequency of the signal and which include a first power source line, a second power source line and a neutral line. The coupling circuit has a transformer operating at a high frequency and having a primary winding and a secondary winding. The primary winding is provided for connecting with a device having a communication capability of the signal. The secondary winding has a pair of end terminals provided for connections to the first and second power source lines, respectively, and an intermediate tap provided between the pair of the end terminals for a connection to the neutral line. Capacitors having a capacitance effective to pass the signal of the high frequency and effective to cut off the electric current of the low frequency are inserted into the respective connections to the first power source line, the second power source line and the neutral line.

### BACKGROUND OF THE INVENTION

1. Field of the Invention

The present invention is related to a coupling circuit for power line communication (PLC) which facilitates the power line communication via a distribution board, and a network device for PLC using such a coupling circuit.

2. Description of the Related Art

Nowadays, a power line communication (PLC) which utilizes power lines installed all over the country is being put into practice for digital communication. The PLC is mainly applied to a home network which uses house wiring rather than remote communication which uses high voltage lines. (See non-patent document 1).

Recently, even for domestic use, a single-phase three-line system is used in Japan to bring electricity from a main power line into a home. FIG. 4 shows an example of a distribution panel of a single-phase three-line type. Three lines, L1, L2, and N are routed in the distribution board via a service breaker 100. Each of three pairs of lines, L1-L2, L1-N, and L2-N respectively provides electrical power of 200 V or 100 V. Typically, voltage of 100 V is applied for the house wiring, and voltage of 200 V is applied for devices such as an air conditioner, an induction heating cooking device, or a water heater utilizing midnight power.

Note that, for power line communication using a conventional signal having 100 through 450 kHz, there is a technology for bridging a high frequency signal among three power lines, as described in patent document 1.

Non-Patent Document 1: “Report” [online], December 2005, Workshop for Power Line Communication, [searched on Dec. 23, 2007], URL on the internet:

http://www.soumu.go.jp/s-news/2005/pdf/051226_{—}6_bt2.pdf

Patent Document 1: Japanese Patent No. 2629131

The PLC is designed to allow an electrical device connected to an end point of the house wiring to send and receive a high frequency digital signal. Therefore, the PLC signal is transmitted on any one of the three pairs of lines mentioned above. As such, a problem arises wherein a signal carried on any one pair of lines is not delivered to electric devices connected to the other two pairs of lines. More specifically, a PLC signal sent from a device connected to a line pair L1-N is not delivered to an electronic device connected to a line pair L2-N or line pair L1-L2, and a PLC signal sent from a device connected to a line pair L2-N is not delivered to an electronic device connected to a line pair L1-N or line pair L1-L2. Likewise, a PLC signal sent from a device connected to a line pair L1-L2 is not delivered to an electronic device connected to a line pair L1-N or line pair L2-N.

Also, it is an objective of the PLC to use indoor power wiring LAN for LAN, and to allow such LAN to be connected to WAN internet. However, when the indoor wiring is of a single-phase three-line type, mentioned above, connecting WAN to one of the line pairs is not sufficient for allowing electric devices connected to the other line pairs to access to WAN, which was a problem.

Also, in order to ensure PLC communication between electric devices operating at 100 V, in other words, in order to ensure communication between a line pair L1-N and line pair L2-N, a bypass capacitor may be connected between the line L1-L2. In addition, there are many devices that operate at 200 V in a single-phase three-line system and that include an air conditioner, an induction heater motor and other devices using high frequency. In order to prevent high frequency noise from leaking outside of these devices, a capacitor is connected to a root of an electric cord which is connected to a plug so as to bypass the high frequency signal (noise). If the coupling circuit as described in patent document 1, mentioned above, is connected to such wiring, a problem arises wherein a high frequency bypassing will occur not only between the line L1-L2, but also between the line L1-N, and the line L2-N, which makes it impossible to communicate using PLC in all entire indoor wiring.

### SUMMARY OF THE INVENTION

It is an objective of the present invention to provide a PLC coupling circuit and a PLC network device for facilitating power line communication via a pair of two lines among three indoor power lines extending from the single-phase three-line type distribution board.

In a first aspect of the present invention, there is provided a coupling circuit of a power line communication system for bridging a signal of a high frequency between lines of a single-phase three-line type which feed an electric current having a low frequency as compared to the high frequency of the signal and which include one power source line (L1), another power source line (L2) and a neutral line (N), the coupling circuit comprising: a transformer operating at a high frequency and having a primary winding and a secondary winding, the primary winding being provided for connecting with a device having a communication capability of the signal, the secondary winding having a pair of end terminals provided for connections to the respective power source lines, and an intermediate tap provided between the pair of the end terminals for a connection to the neutral line; and at least two capacitors having a capacitance effective to pass the signal of the high frequency and effective to cut off the electric current of the low frequency, said at least two capacitors being inserted into at least two of the connections to said one power source line, said another power source line and the neutral line.

In a second aspect of the present invention, there is provided a coupling circuit of a power line communication system for bridging a signal of a high frequency between three power lines of a three-phase alternating current type which feed an electric current having a low frequency as compared to the high frequency of the signal, the coupling circuit comprising: a transformer operating at a high frequency and having a primary winding and a secondary winding, the primary winding being provided for connecting with a device having a communication capability of the signal, the secondary winding having a pair of end terminals and an intermediate tap between the pair of the end terminals for connections to the three power lines of the three-phase alternating current type, respectively; and at least two capacitors having a capacitance effective to pass the signal of the high frequency and effective to cut off the electric current of the low frequency, said at least two capacitors being inserted into at least two of the connections to the power lines of the three-phase alternating current type.

In a third aspect of the present invention, there is provided a coupling circuit of a power line communication system for bridging a signal of a high frequency between lines of a single-phase three-line type which feed an electric current having a low frequency as compared to the high frequency of the signal and which include one power source line, another power source line and a neutral line, the coupling circuit comprising: a line connector that is provided for a connection to one of the power source lines; a transformer operating at a high frequency and having a primary winding and first and second secondary windings, the primary winding being provided for connecting with a device having a communication capability of the signal, the first secondary winding having a pair of end terminals, the second secondary winding having a pair of end terminals, one of the pair of the end terminals of the second secondary winding being provided for a connection to the neutral line, and the other of the pair of the end terminals of the second secondary winding being provided for a connection to the other of the power source lines; a switch that reversibly connects the end terminals of the first secondary winding to the line connector and the one of the pair of the terminals of the second secondary winding, so that the first secondary winding is selectably placed in either of a forward connection to the second secondary winding or a reverse connection to the second secondary winding; and at least two capacitors having a capacitance effective to pass the signal of the high frequency and effective to cut off the electric current of the low frequency, said at least two capacitors being inserted into at least two of the connections to said one power source line, said another power source line and the neutral line.

In a fourth aspect of the present invention, there is provided a coupling circuit of a power line communication system for bridging a signal of a high frequency between lines of a single-phase three-line type which feed an electric current having a low frequency as compared to the high frequency of the signal and which include one source line, another power source line and a neutral line, the coupling circuit comprising: a transformer operating at a high frequency and having a primary winding and a secondary winding, the primary winding being provided for connecting with a device having a communication capability of the signal, the secondary winding having a pair of end terminals and an intermediate tap between the pair of the end terminals, one of the pair of the end terminals being provided for a connection to one of the power source lines, the intermediate tap being provided for a connection to the neutral line; a switch having a common contact and a pair of selectable contacts that are switchably coupled to the common contact, the common contact being provided for a connection to the other of the power source lines, the pair of the selectable contacts being connected to the pair of the end terminals of the secondary winding; and at least two capacitors having a capacitance effective to pass the signal of the high frequency and effective to cut off the electric current of the low frequency, said at least two capacitors being inserted into at least two of the connections to said one power source line, said another power source line and the neutral line.

In a fifth aspect of the present invention, there is provided a network device for use in a power line communication system, comprising the coupling circuit as describe in any one of the first to fourth aspects of the invention; and a communication controller having first and second network terminals, the communication controller being configured to forward the signal inputted from the first network terminal to the second network terminal and to forward the signal inputted from the second network terminal to the first network terminal, the first network terminal being coupled to the primary winding of the coupling circuit, the second network terminal being coupled to a communication network of the signal.

In accordance with the present invention, a signal input into the primary winding can be delivered to all three pairs of the power lines of three-line type (single-phase three-line type or three-phase AC type) via the secondary winding of the transformer, as well as all signals input from each pair of the power lines of three-line type can be output from the primary winding via the secondary winding, enabling for an outside device connected to the primary winding to communicate with inside devices connected to any pair of the power lines of above-mentioned three line type. In addition, in the present invention, a signal input from any one pair of the three line type power lines is also communicated on the other two line pairs, enabling each of the three line pairs to communicate with each other.

Further, in accordance with the present invention, even when a high frequency bypassing has occurred between the lines L1 and L2, bypassing can be prevented on the secondary winding using the switch, to ensure that outside devices connected to the primary winding and inside devices connected to line pair L1-N or L2-N can communicate with each other.

### BRIEF DESCRIPTION OF THE DRAWINGS

FIG. 1 is a diagram showing a structure of a distribution board using a PLC network device in accordance with a first embodiment of the present invention.

FIG. 2 is a diagram showing a structure of a PLC network device in accordance with a second embodiment of the present invention.

FIG. 3 is a diagram showing a structure of a PLC network device in accordance with a third embodiment of the present invention.

FIG. 4 is a diagram showing a structure of a typical distribution board.

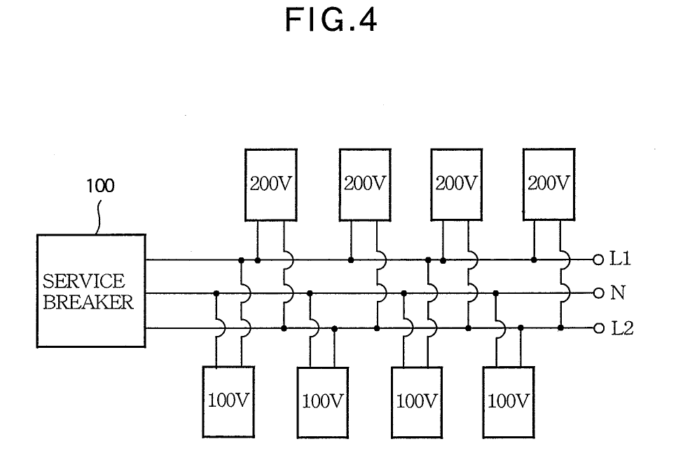

### DESCRIPTION OF THE PREFERRED EMBODIMENTS

A network device for PLC in accordance with embodiments of the present invention will be described with reference to the drawings. The PLC network device is intended to equally connect three pairs of single-phase three-line type indoor power lines, drawn from a main power line, to WAN internet.

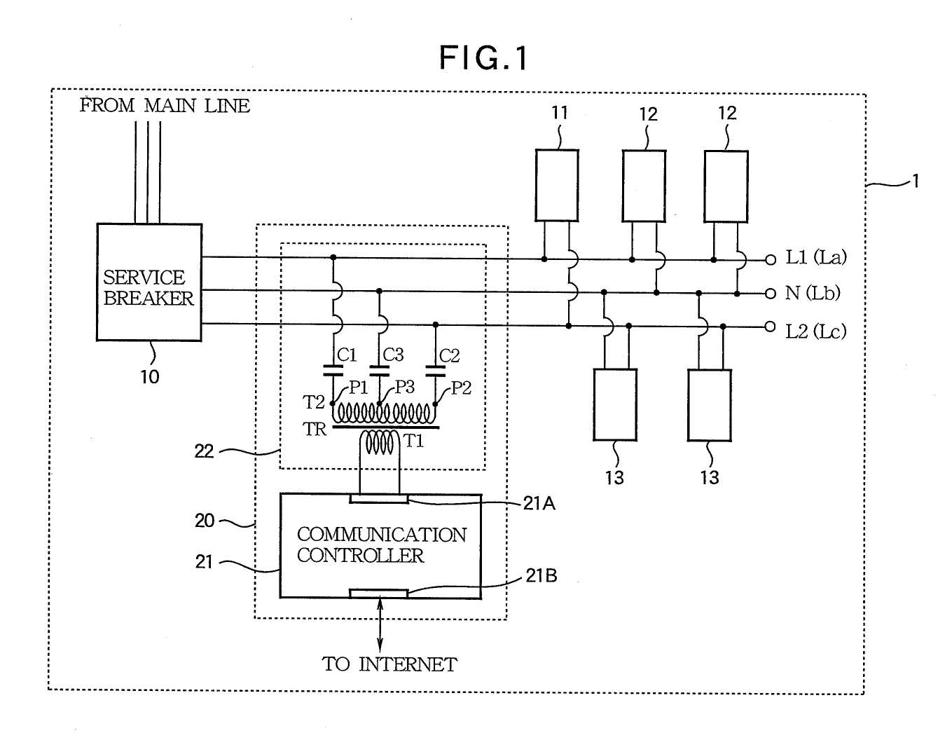

FIG. 1 is a diagram showing a structure of a distribution board incorporating a PLC network device in accordance with a first embodiment of the present invention. The distribution board 1 is connected to a single-phase three-line power main line such as those carried by electric poles. The single-phase three-line type power lines are output from the distribution board as power source lines L1 and L2, and a neutral line N via a service breaker (a current limiter) 10 of a three-line type. In some case, the neutral line may be grounded and therefore may serve as a ground line. Three different pairs can be formed with these three lines, and voltage of 200 V or 100 V can be carried on each pair. More specifically, there are three pair combinations of the lines wherein line pairs L1-N and L2-N may carry voltage of 100 V, and a line pair L1-L2 may carry voltage of 200 V.

A safety breaker (a circuit breaker) 11, which is a two-line type breaker, connected to the line pair L1-L2 draws voltage of 200 V. A safety breaker 12, connected to the line pair L1-N to draw voltage of 100 V. A safety breaker 13, connected to the line pair L2-N to draw voltage of 100 V. Line load on each of the line pairs L1-N and L2-N is appropriately distributed therebetween so as to each have similar amount of line load (in other words, so as to minimize amount of current flowing on the neutral line N). The safety breaker 11 which draws voltage of 200 V is connected to outlets for devices to be operated at 200 V such as an air conditioner. The safety breakers 12 and 13 are connected to outlets for general electric devices or lighting fixtures.

The devices connected to lines extending out of each of the breakers 11˜13 send PLC signals. Then, the PLC signals appear on the three types of line pairs L1-N, L2-N, and L1-L2 in the distribution board. In order to receive and deliver PLC signals originating from all of these devices to WAN, a network device must be connected to each line pair.

From the opposite point of view, the devices connected to lines extending out of each of the breakers 11˜13 wait to receive PLC signals. When the PLC signals appear on the three types of line pairs L1-N, L2-N, and L1-L2 in the distribution board, in order to send the PLC signals to all of these devices, a network device must be connected to each line pair.

As such, a PLC network device 20 shown in FIG. 1 is configured to connect three power lines to signal lines such that a signal from WAN can be carried on all three line pairs, and a signal coming from all three line pairs can be received. The network device 20 has a LAN terminal 21A (a first network terminal), a WAN terminal 21B (a second network terminal), a communication controller 21 for relaying communication between the internet and LAN employing power line communication, and a connection portion 22 (a coupling circuit or bridge circuit) for sending a signal from the internet to three line pairs and to receive a signal sent from the three line pairs.

The connection portion 22 has a high frequency transformer TR. The high frequency transformer TR has for example, a primary winding T1 and a secondary winding T2, both of which are wound around ferrite toroidal cores. The secondary winding has end terminals P1, P2, and an intermediate tap P3. The intermediate tap may not be necessarily provided on a position having exact equidistance from each end. One terminal P1 of the secondary winding is connected to the power source line L1 via the capacitor C1. The other terminal P2 of the secondary winding is connected to the power source line L2 via the capacitor C2. The intermediate tap P3 is connected to the neutral line N via the capacitor C3. Note that, at least two capacitors are needed, therefore any one of the capacitors C1 to C3 may be omitted. Generally, if one of the capacitors C1 to C3 is omitted, the capacitor C3 connected to the neutral line is omitted.

The PLC (power line communication) signal has a frequency such as ranging from 2 to 30 MHz. Power source frequency is 50 Hz or 60 Hz in Japan. Capacitance of the capacitors C1, C2, C3 is such that it blocks current at the above-mentioned power source frequency to allow the PLC signal to pass through.

The communication controller 21 is connected to the connection portion 22 via the LAN terminal 21A, and to the internet via the WAN terminal 21B. The communication controller 21 receives downstream signal from the internet to supply the signal to the connection portion 22 and receives upstream signal from the connection portion 22 to forward the signal to the internet.

The signal received by the communication controller 21 from the internet via the WAN terminal 21B is supplied to the primary winding T1 of the high frequency transformer TR via the LAN terminal 21A. By electromagnetic induction, the signals received from the internet appear on the secondary winding T2 terminals P1-P2, P1-P3, and P2-P3 of the high frequency transformer TR at a potential determined by the number of windings of the primary and secondary windings, and then are applied to the line pairs L1-L2, L1-N, and L2-N, respectively. Therefore, signals from the internet can be transmitted with the same conditions to any devices connected to any one of the above-mentioned breakers 11, 12, and 13.

Likewise, the PLC signal sent by the devices connected to the breaker 11 is applied across the terminals P1 and P2 of the secondary winding T2 in the connection portion 22 via the power source line L1 and L2. Note that, current at the power source frequency are blocked by the capacitors C1 and C2. When the signal is supplied to the secondary winding T2, by electromagnetic induction, the signal also appears on the primary winding T1 and then is transmitted to the communication controller 21. The communication controller 21 forwards the signal to the internet.

In the same way, the PLC signals sent by the devices connected to the breaker 12 is applied across the terminals P1 and P3 of the secondary winding T2 in the connection portion 22 via the power source line L1 and the neutral line N. The PLC signals sent by the devices connected to the breaker 13 is applied across the terminals P2 and P3 of the secondary winding T2 in the connection portion 22 via the power source line L2 and the neutral line N. Note that, current at the power source frequency are blocked by the capacitors C1, C2, C3. When the signal is supplied to the secondary winding T2 in this way, by electromagnetic induction, the signal also appears on the primary winding T1 and then is transmitted to the communication controller 21. The communication controller 21 forwards the signal to the internet.

In addition, when the PLC signal sent by the devices connected to the breaker 11 is applied across the terminals P1 and P2 of the secondary winding T2 in the connection portion 22 via the power source line L1 and L2, by self-induction, induced current flows across the terminals P1-P3 and P2-P3. In this way, the PLC signal sent on the line pair L1-L2 at 200 V can also be transmitted to the devices connected with any one of the other line pairs L1-N and L2-N.

In the same way, when the PLC signal sent by the devices connected to the breaker 12 is applied across the terminals P1 and P3 of the secondary winding T2 in the connection portion 22 via the power source line L1 and the neutral line N, by self-induction, induced current flows across the terminals P1-P2 and P2-P3. Also, when the PLC signal sent by the devices connected to the breaker 13, is applied across the terminals P2 and P3 of the secondary winding T2, in the connection portion 22 via the power source line L2 and the neutral line N, by self-induction, induced current flows across the terminals P1-P2 and P1-P3. In this way, the PLC signal sent on the line pair L1-N or L2-N at 100 V can also be transmitted to the devices connected with any one of the other line pairs L1-L2, L1-N and L2-N.

Note that, the communication controller 21 not only forwards the PLC signal (a packet) to WAN and forwards the signal from WAN to the PLC network, but also may be able to perform network communication controlling processing such as address conversion and packet encapsulation.

Note that, while the above-mentioned embodiment is described in terms of a PLC network device, applied to single-phase three-line type power line, the embodiment may be applied to PLC network device for use in three-phase alternating current type power line as well. Namely, as depicted in FIG. 1, the coupling circuit 22 may be used in a power line communication system for bridging a signal of a high frequency between three power lines La, Lb and Lc of a three-phase alternating current type which feed an electric current having a low frequency as compared to the high frequency of the signal. The high frequency transformer TR operating at a high frequency has a primary winding T1 and a secondary winding T2. The primary winding T1 is provided for connecting with a device 21 having a communication capability of the signal. The secondary winding T2 has a pair of end terminals P1, P2 and an intermediate tap P3 between the pair of the end terminals P1, P2 for connections to the three power lines La, Lb and Lc of the three-phase alternating current type. Capacitors C1, C2 and C3 having a capacitance effective to pass the signal of the high frequency and effective to cut off the electric current of the low frequency are inserted into the respective connections to the power lines La, Lb and Lc of the three-phase alternating current type.

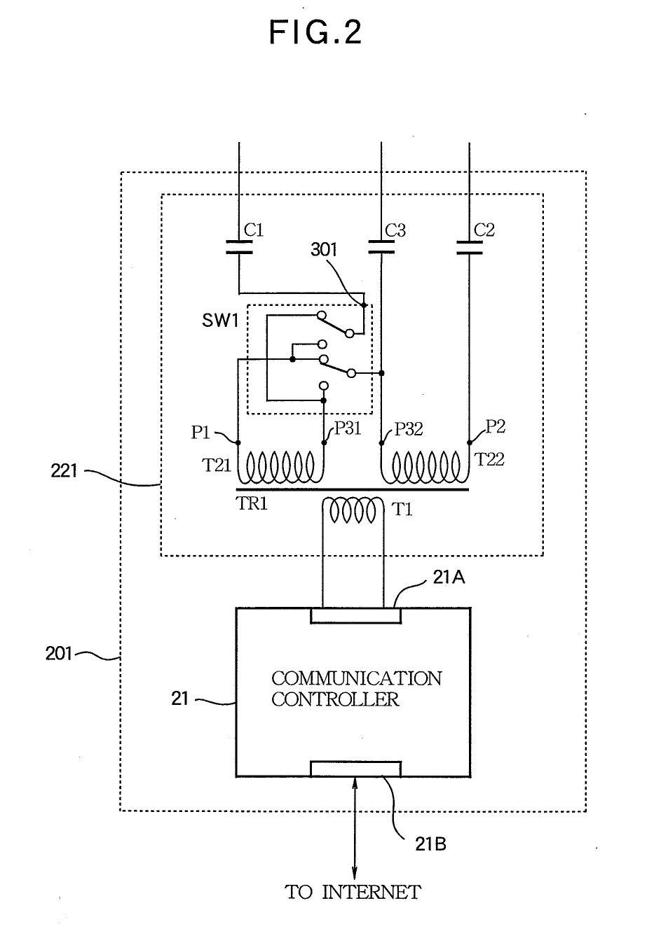

FIG. 2 is a diagram showing a PLC network device in accordance with a second embodiment of the present invention. In FIG. 2, the components having the same configuration as those shown in FIG. 1 are referenced using the same numerals in FIG. 1, and will not be described further. The PLC network device 201 shown in FIG. 2 is different from the PLC network device 20 in terms of configuration in that the transformer TR1 in a connection portion 221 has two secondary windings T21 and T22, and in that winding direction thereof can be changed by switching between one state where the two secondary windings T21 and T22 have opposite winding directions with each other and another state where the two secondary windings T21 and T22 have the same winding direction with each other.

Terminals P2 (where the winding ends) and P32 (where the winding starts) at each end of the L2 side secondary winding T22 are connected to the power source line L2 and the neutral line N via the capacitor C2 and C3, respectively. On the other hand, terminals P1 (where the winding starts) and P31 (where the winding ends) at each end of the L1 side secondary winding T21 are connected to a switch SW1.

The selector switch SW1 is a double pole double throw (two-circuit two-contact) switch which selects either a forward connection wherein P1 is connected to C1 and P31 is connected to C3 (P32) or wherein P1 is connected to C3 and P31 is connected to C1 (reverse connection). A common contact in a first circuit of the selector switch SW1 is connected to the power source line L1 via the capacitor C1, and a common contact in a second circuit, together with the terminal P32 of the secondary winding T22 is connected to the neutral line N via the capacitor C3. The terminal P31 of the secondary winding T21 is connected to an upper selectable contact in the first circuit and a lower selectable contact in the second circuit. The terminal P1 of the secondary winding T21 is connected to an lower selectable contact in the first circuit and an upper selectable contact in the second circuit.

When the selector switch SW1 is in a first state wherein the upper contacts in the first and second circuits are connected to the common contacts in the first and second circuits, respectively, the terminal P1 is connected to the neutral line N via the capacitor C3 (the second circuit), and the terminal P 31 is connected to the power source line L1 via the capacitor C1 (the first circuit). In this first state, the winding start terminal P1 of the secondary winding T21 is connected to the winding start terminal P32 of the secondary winding T22, so as to form the reverse connection (cross connection). The illustrated state shows the reverse connection.

Note that, the terminal 301 of the common contact in the first circuit for the above-mentioned selector switch SW1 corresponds to the line connector or the power line connection portion.

On the other hand, When the selector switch SW1 is in a second state wherein the lower contacts in the first and second circuits are connected to the common contacts in the first and second circuits, respectively, the terminal P1 is connected to the power source line L1 via the capacitor C1 (the first circuit), and the terminal P 31 is connected to the neutral line N via the capacitor C3 (the second circuit). In this second state, the winding end terminal P31 of the secondary winding T21 is connected to the winding start terminal P32 of the secondary winding T22, so as to form a serial connection referred to as the forward connection (straight connection).

In the forward connection, the configuration is similar to that of the network device shown in FIG. 1. In the forward connection, for example, if a capacitor is inserted between the line pairs L1-L2, which may bypass a high frequency signal, the secondary winding of the transformer will be bypassed in terms of the high frequency component, which makes it impossible to communicate on all line pairs. The capacitor which may be inserted between the line pair L1-L2 and bypass the high frequency signal includes, for example, a bypass capacitor for ensuring the PLC communication between 100 V devices, i.e. communication between the line pairs L1-N and L2-N, a bypass capacitor for preventing high frequency noise generated in an electrical device connected to a 200 V outlet from entering into the power line, or the like.

With this configuration, when a high frequency signal is bypassed between the line pair L1-L2, the switch can be placed in the first state (reverse connection) as shown in FIG. 2, thereby a signal having the same phase as that output from the secondary windings T21 and T22 appears in between the line pairs L1→N and L2→N, respectively. Thus, a signal at the same potential appears on the power source lines L1 and L2 with reference to the neutral line N, therefore, the high frequency bypassing between L1-L2 is not a problem, and communication from the primary winding T1 to the line pairs L1-N and L2-N can be ensured. While the above description is for the case wherein a signal is transmitted from the primary winding to the secondary windings, the same description can be applied to the case wherein a signal is transmitted from the secondary windings to the primary winding. In this case, communication on the line pair L1-L2 is abandoned, however, each communication between the primary winding T1 and the secondary winding T21 (line pair L1-N) and T22 (line pair L2-N) can be ensured.

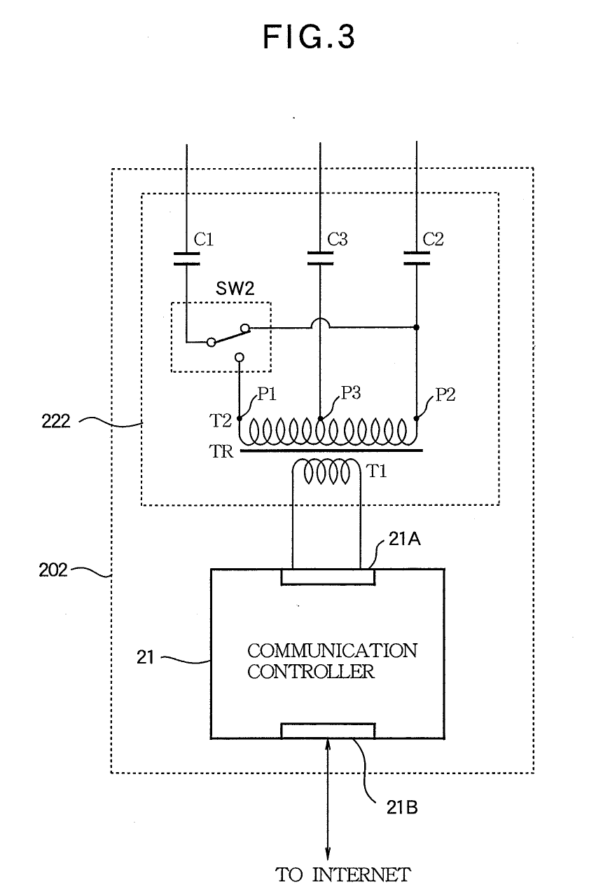

FIG. 3 is a diagram showing a PLC network device in accordance with a third embodiment of the present invention. In this figure, the components having the same configuration as those shown in FIG. 1 are referenced using the same numerals, and will not be described further. The PLC network device 202 shown in FIG. 3 is different from the PLC network device 20 shown in FIG. 1 in terms of configuration in that the terminal of the secondary winding T2 to be connected to the capacitor C1 (power source line L1) can be switched between the terminal P1 and P2 by a selector switch SW2.

The selector switch SW2 is a single pole double throw (one-circuit two-contact) switch which selects whether the capacitor C1 is connected to the terminal P1 as described above or to the terminal P2. A common contact in this selector switch SW2 is connected to the power source line L1 via the capacitor C1. An upper selectable contact is connected to the terminal P2 of the secondary winding T2, and a lower selectable contact is connected to the terminal P1 of the secondary winding T2.

When the selector switch SW2 is in the first state, wherein the upper selectable contact is connected to the common contact, the terminal P2 is connected to the power source line L1 via the capacitor C1. The terminal P2 of the secondary winding T2 is also connected to the power source line L2, resulting in forming a high frequency bypassing connection with the power source lines L1 and L2. However, in this situation, the terminal P1 of the secondary winding T2 is not connected to the capacitor C1, and in open state, therefore, the secondary winding T2 is not bypassed. The bypassed state is shown the figure.

On the other hand, when the selector switch SW2 is in the second state wherein the lower selectable contact is connected to the common contact, the terminal P1 is connected to the power source line L1 via the capacitor C1. This connection state (normal connection) is similar to that of the first embodiment shown in FIG. 1, therefore operation thereof will not described further.

In the present embodiment, as described in the second embodiment, when a high frequency signal is bypassed between the line L1-L2, the selector switch SW2 can be placed in the first state to form a bypassed connection, thereby a signal having the same phase as that output from the portion of the secondary winding from the terminal P2 to the intermediate tap P3 is applied between the line pairs L1→N and L2→N. As described above, the terminal P1 of the secondary winding is in the open state, so the portion of the secondary winding from the terminal P1 to the intermediate tap P3 is not functioning. However, this does not lead to bypass all of the secondary winding T2, and a signal appears on the portion of the secondary winding from the terminal P2 to the intermediate tap P3. Thus, a signal at the same potential appears on the power source lines L1 and L2 with reference to the neutral line N, therefore, the high frequency bypassing between the power source lines L1 and L2 is not a problem, and communication from the primary winding T1 to the line pairs L1-N and L2-N can be ensured. While the above description is for the case wherein a signal is transmitted from the primary winding to the secondary windings, the same description can be applied to the case wherein a signal is transmitted from the secondary windings to the primary winding. In this case, communication on the line pair L1-L2 is abandoned, however, each communication between the primary winding T1 and the line pairs L1-N and L2-N can be ensured.

With the configuration in accordance with the third embodiment shown in FIG. 3, when in the bypassed connection, about half of the secondary winding T2 (which corresponds to the portion from the intermediate tap P3 to the terminal P2) is functioning, and the remaining portion (which corresponds to the portion from the terminal P1 to the intermediate tap P3) is in open state. However, in this configuration, the needed number of secondary winding of the high frequency transformer TR is just one with the intermediate tap, and the switch selector SW can be a single pole double throw switch, which simplifies circuit configuration.

In the embodiments described above, changing the state of the selector switch SW1 and SW2 may occur automatically in response to detection of the bypassing state between the line L1 and L2, or may be occurred manually by personnel in consideration of the communication condition.

In the first, second and third embodiments as described above, while the network connected to the opposite side of the connection portions 22, 221, and 222 in the communication controller 21 has been described as WAN (Internet), but a separate LAN network may be connected.

Further, while the device connected to the primary winding terminal T1 side of the connection portions 22, 221, and 222 has been shown as the communication controller 21, having a communication capability with other networks, the device connected to the primary winding terminal T1 side is not limited to such a communication controller. For example, a home monitor for monitoring electrical devices and the like in the house, or a content server for distributing content such as music in the house may be connected. Note that, the above-mentioned home monitor and content server are only needed to have a capability to communicate with the devices connected to the power lines L1, L2, and N, and not necessarily have a capability to communicate with the other networks such as the internet.

If the above-mentioned home monitor and content server have a capability to communicate with the other networks, using the communication capability, communication for their own operation such as alarm notification of the home monitor or content download of the content server may be carried out in conjunction with the above-mentioned communication for relying communication of the devices, such as the communication controller 21 described above, connected to the power line.

1. A coupling circuit of a power line communication system for bridging a signal of a high frequency between lines of a single-phase three-line type which feed an electric current having a low frequency as compared to the high frequency of the signal and which include one power source line, another power source line and a neutral line, the coupling circuit comprising:
a transformer operating at a high frequency and having a primary winding and a secondary winding, the primary winding being provided for connecting with a device having a communication capability of the signal, the secondary winding having a pair of end terminals provided for connections to the respective power source lines, and an intermediate tap provided between the pair of the end terminals for a connection to the neutral line; and
at least two capacitors having a capacitance effective to pass the signal of the high frequency and effective to cut off the electric current of the low frequency, said at least two capacitors being inserted into at least two of the connections to said one power source line, said another power source line and the neutral line.

2. A coupling circuit of a power line communication system for bridging a signal of a high frequency between three power lines of a three-phase alternating current type which feed an electric current having a low frequency as compared to the high frequency of the signal, the coupling circuit comprising:
a transformer operating at a high frequency and having a primary winding and a secondary winding, the primary winding being provided for connecting with a device having a communication capability of the signal, the secondary winding having a pair of end terminals and an intermediate tap between the pair of the end terminals for connections to the three power lines of the three-phase alternating current type, respectively; and
at least two capacitors having a capacitance effective to pass the signal of the high frequency and effective to cut off the electric current of the low frequency, said at least two capacitors being inserted into at least two of the connections to the power lines of the three-phase alternating current type.

3. A coupling circuit of a power line communication system for bridging a signal of a high frequency between lines of a single-phase three-line type which feed an electric current having a low frequency as compared to the high frequency of the signal and which include one power source line, another power source line and a neutral line, the coupling circuit comprising:
a line connector that is provided for a connection to one of the power source lines;
a transformer operating at a high frequency and having a primary winding and first and second secondary windings, the primary winding being provided for connecting with a device having a communication capability of the signal, the first secondary winding having a pair of end terminals, the second secondary winding having a pair of end terminals, one of the pair of the end terminals of the second secondary winding being provided for a connection to the neutral line, and the other of the pair of the end terminals of the second secondary winding being provided for a connection to the other of the power source lines;
a switch that reversibly connects the end terminals of the first secondary winding to the line connector and the one of the pair of the terminals of the second secondary winding, so that the first secondary winding is selectably placed in either of a forward connection to the second secondary winding or a reverse connection to the second secondary winding; and
at least two capacitors having a capacitance effective to pass the signal of the high frequency and effective to cut off the electric current of the low frequency, said at least two capacitors being inserted into at least two of the connections to said one power source line, said another power source line and the neutral line.

4. A coupling circuit of a power line communication system for bridging a signal of a high frequency between lines of a single-phase three-line type which feed an electric current having a low frequency as compared to the high frequency of the signal and which include one power source line, another power source line and a neutral line, the coupling circuit comprising:
a transformer operating at a high frequency and having a primary winding and a secondary winding, the primary winding being provided for connecting with a device having a communication capability of the signal, the secondary winding having a pair of end terminals and an intermediate tap between the pair of the end terminals, one of the pair of the end terminals being provided for a connection to one of the power source lines, the intermediate tap being provided for a connection to the neutral line;
a switch having a common contact and a pair of selectable contacts that are switchably coupled to the common contact, the common contact being provided for a connection to the other of the power source lines, the pair of the selectable contacts being connected to the pair of the end terminals of the secondary winding; and
at least two capacitors having a capacitance effective to pass the signal of the high frequency and effective to cut off the electric current of the low frequency, said at least two capacitors being inserted into at least two of the connections to said one power source line, said another power source line and the neutral line.

5. A network device for use in a power line communication system, comprising:
a coupling circuit for bridging a signal of a high frequency between lines of a single-phase three-line type which feed an electric current having a low frequency as compared to the high frequency of the signal and which include one power source line, another power source line and a neutral line,
wherein the coupling circuit comprises:
a transformer operating at a high frequency and having a primary winding and a secondary winding, the primary winding being provided for connecting with a device having a communication capability of the signal, the secondary winding having a pair of end terminals provided for connections to the respective power source lines, and an intermediate tap provided between the pair of the end terminals for a connection to the neutral line; and
at least two capacitors having a capacitance effective to pass the signal of the high frequency and effective to cut off the electric current of the low frequency, said at least two capacitors being inserted into at least two of the connections to said one power source line, said another power source line and the neutral line; and
a communication controller having first and second network terminals, the communication controller being configured to forward the signal inputted from the first network terminal to the second network terminal and to forward the signal inputted from the second network terminal to the first network terminal, the first network terminal being coupled to the primary winding of the coupling circuit, the second network terminal being coupled to a communication network of the signal.

6. A network device for use in a power line communication system, comprising:
a coupling circuit for bridging a signal of a high frequency between three power lines of a three-phase alternating current type which feed an electric current having a low frequency as compared to the high frequency of the signal,
wherein the coupling circuit comprises:
a transformer operating at a high frequency and having a primary winding and a secondary winding, the primary winding being provided for connecting with a device having a communication capability of the signal, the secondary winding having a pair of end terminals and an intermediate tap between the pair of the end terminals for connections to the three power lines of the three-phase alternating current type, respectively; and
at least two capacitors having a capacitance effective to pass the signal of the high frequency and effective to cut off the electric current of the low frequency, said at least two capacitors being inserted into at least two of the connections to the power lines of the three-phase alternating current type; and
a communication controller having first and second network terminals, the communication controller being configured to forward the signal inputted from the first network terminal to the second network terminal and to forward the signal inputted from the second network terminal to the first network terminal, the first network terminal being coupled to the primary winding of the coupling circuit, the second network terminal being coupled to a communication network of the signal.

7. A network device for use in a power line communication system, comprising:
a coupling circuit for bridging a signal of a high frequency between lines of a single-phase three-line type which feed an electric current having a low frequency as compared to the high frequency of the signal and which include one power source line, another power source line and a neutral line,
wherein the coupling circuit comprises:
a line connector that is provided for a connection to one of the power source lines;
a transformer operating at a high frequency and having a primary winding and first and second secondary windings, the primary winding being provided for connecting with a device having a communication capability of the signal, the first secondary winding having a pair of end terminals, the second secondary winding having a pair of end terminals, one of the pair of the end terminals of the second secondary winding being provided for a connection to the neutral line, and the other of the pair of the end terminals of the second secondary winding being provided for a connection to the other of the power source lines;
a switch that reversibly connects the end terminals of the first secondary winding to the line connector and the one of the pair of the terminals of the second secondary winding, so that the first secondary winding is selectably placed in either of a forward connection to the second secondary winding or a reverse connection to the second secondary winding; and
at least two capacitors having a capacitance effective to pass the signal of the high frequency and effective to cut off the electric current of the low frequency, said at least two capacitors being inserted into at least two of the connections to said one power source line, said another power source line and the neutral line; and
a communication controller having first and second network terminals, the communication controller being configured to forward the signal inputted from the first network terminal to the second network terminal and to forward the signal inputted from the second network terminal to the first network terminal, the first network terminal being coupled to the primary winding of the coupling circuit, the second network terminal being coupled to a communication network of the signal.

8. A network device for use in a power line communication system, comprising:
a coupling circuit for bridging a signal of a high frequency between lines of a single-phase three-line type which feed an electric current having a low frequency as compared to the high frequency of the signal and which include one power source line, another power source line and a neutral line,
wherein the coupling circuit comprises:
a transformer operating at a high frequency and having a primary winding and a secondary winding, the primary winding being provided for connecting with a device having a communication capability of the signal, the secondary winding having a pair of end terminals and an intermediate tap between the pair of the end terminals, one of the pair of the end terminals being provided for a connection to one of the power source lines, the intermediate tap being provided for a connection to the neutral line;
a switch having a common contact and a pair of selectable contacts that are switchably coupled to the common contact, the common contact being provided for a connection to the other of the power source lines, the pair of the selectable contacts being connected to the pair of the end terminals of the secondary winding; and
at least two capacitors having a capacitance effective to pass the signal of the high frequency and effective to cut off the electric current of the low frequency, said at least two capacitors being inserted into at least two of the connections to said one power source line, said another power source line and the neutral line; and
a communication controller having first and second network terminals, the communication controller being configured to forward the signal inputted from the first network terminal to the second network terminal and to forward the signal inputted from the second network terminal to the first network terminal, the first network terminal being coupled to the primary winding of the coupling circuit, the second network terminal being coupled to a communication network of the signal.
